(19) United States
(12) Patent Application Publication
(10) Pub. No.: US 2012/0319292 A1
(43) Pub. Date: Dec. 20, 2012

(54) STRUCTURE OF A WAFER LEVEL SUBSTRATE FOR CARRYING LIGHT EMITTING DEVICES

(75) Inventors: Sin-Hua Ho, Tainan City (TW); Nai-Yuan Tang, Tainan City (TW); Chuan-Ching Hsueh, Tainan City (TW)

(73) Assignee: HIMAX TECHNOLOGIES LIMITED, Tainan City (TW)

(21) Appl. No.: 13/161,297

(22) Filed: Jun. 15, 2011

(51) Int. Cl. H01L 23/48

(52) U.S. Cl. 257/774; 257/E23.011

(57) ABSTRACT

Structure and fabricating method of a wafer level substrate for carrying light emitting devices are provided in present invention. The wafer level silicon substrate structure includes a first substrate and a second substrate. A metal line is constructed on a surface of the first substrate according to a predetermined pattern. The predetermined pattern is divided into a plurality of first portions and a plurality of second portions. The second substrate is adhered to the surface of the first substrate. The second substrate has a plurality of through holes. Each of the through holes is respectively corresponding to the first portions. Each of the first portions is adapted to electrically connect with a light emitting device. The provided wafer level substrate structure configured with light emitting devices is capable of providing uniform light output, having better light extraction property, improving process yield, higher production yield and achieving product uniformity.

### BACKGROUND OF THE INVENTION

1. Field of the Invention

The present invention generally relates to a structure of a substrate. More particularly, the present invention relates to a structure of a wafer level substrate for carrying light emitting devices such as light emitting diodes (LED).

2. Description of Related Art

Nowadays, compared to other light source such as incandescence, light emitting diodes (LED) are not only able to significantly reduce power consumption, but also can have longer lifetimes, faster response speed, compact size, lower maintenance cost and grater reliability. Therefore, they are widely used since their inception in the early 60's. Moreover, with the gradually developed deposition techniques, feasibility of LED with much higher brightness than traditional devices brings new applications such as backlighting for displays, automotive lighting and new consumer products like flash for mobile camera or compact projects.

With the development of LED manufacturing process, the development of wafer level fabricating and packaging technology of silicon substrates for light emitting devices also becomes widespread. The wafer level fabricating and packaging technology of silicon substrates for light emitting devices is realized by the silicon based multi-chip LED packaging technology which can tremendously improve the optical properties of LED packaging like optical efficiency and reduction of manufacturing cost.

Silicon substrates are generally used as the carriers of LED in the existing fabricating process of silicon substrate for wafer level LED. The openings are formed in the substrates to embed the LED. Etching process, especially wet etching process, is commonly used to form openings in the substrate. However, the etching process of silicon substrates may bring about some drawbacks like defects forming on the opening surface, disuniformity of etching results and low yield rate. Since etching process of silicon substrate is much affected by the crystal lattice structures of silicon, the above mentioned drawbacks are inevitable. The disuniformity of etching results and defects may cause the deterioration of light reflecting performance. Moreover, the shape and structure of the opening is also restricted because of the crystal lattice structures of silicon.

### SUMMARY OF THE INVENTION

Accordingly, the present invention is directed to a wafer level substrate structure for carrying light emitting devices (LED) capable of providing uniform light output, having better light extraction property, improving process yield and achieving product uniformity.

The present invention is directed to a method of fabricating the aforementioned wafer level substrate for carrying LED.

As embodied and broadly described herein, the present invention provides a wafer level substrate structure to carry light emitting devices including a first substrate and a second substrate. A metal line is constructed on a surface of the first substrate according to a predetermined pattern. The predetermined pattern is divided into a plurality of first portions and a plurality of second portions. The second substrate is adhered to the surface of the first substrate. The second surface has a plurality of through holes, wherein each of the through holes is respectively corresponding to the first portions. Each of the first portions is adapted to electrically connect with at least one light emitting device.

According to an embodiment of the present invention, the first substrate is a silicon substrate or a ceramic substrate, and the second substrate is a glass substrate, a silicon substrate or a sapphire substrate.

According to an embodiment of the present invention, the through holes of the second substrate are formed by a computer numerical control (CNC) process, laser drilling process, dry etching process or wet etching process.

According to an embodiment of the present invention, each of the through holes has an internal wall and an angle between a normal vector of the internal wall and a normal vector of the surface of the first substrate is from 30 to 60 degrees.

According to an embodiment of the present invention, the through hole is a conical hole, any angle conical hole, a rectangular hole, a square hole, or a trapezoidal hole.

According to an embodiment of the present invention, a reflective layer is formed on an internal wall of each of the through holes.

According to an embodiment of the present invention, a reflectivity of the reflective layer is greater than 80 percent.

According to an embodiment of the present invention, the reflective layer is a metal layer.

According to an embodiment of the present invention, the reflective layer is formed by a coating, electroplating, evaporation or sputter process.

According to an embodiment of the present invention, the first substrate and the second substrate are connected by a wafer-to-wafer bonding method or a wafer-to-wafer stacked method.

According to an embodiment of the present invention, the wafer level substrate structure and the light emitting device are connected through a technique of ball grid array (BGA) package or surface mount technology (SMT), or through general electric wires.

The present invention further provides a method of fabricating a wafer level substrate for carrying light emitting devices including the following steps. First, a first substrate is provided, and a metal line is constructed on the first substrate. Herein, the metal line is constructed on a surface of the first substrate according to a predetermined pattern, and the predetermined pattern is divided into a plurality of first portions and a plurality of second portions. Then, a second substrate is provided, and a plurality of through holes is formed on the second substrate. Next, the second substrate is adhered to the surface of the first substrate. Herein, each of the through holes is respectively corresponding to the first portions, and each of the first portions is adapted to electrically connect with at least one light emitting device.

In view of the above, according to the embodiments of the present invention, because of using the second substrate, it is possible to avoid all the drawbacks of the prior silicon substrate obtained by etching silicon process. Through the second substrate, the provided wafer level substrate structure for carrying light emitting devices is capable of providing uniform light output, having better light extraction property, improving process yield and achieving product uniformity. In addition, the shape and structure of the through hole is no longer constrained because of the easy-to-process second substrate is used in the present invention.

In order to make the above features and advantages of the present invention comprehensible, embodiments are described in detail below with the accompanying drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view showing a wafer level substrate structure according to an embodiment of the present invention.

FIG. 1B is a top view showing a through hole of the wafer level substrate structure in FIG. 1A.

FIG. 2A to 2E is a cross-sectional view showing fabricating steps of the wafer level substrate structure in FIG. 1A.

FIG. 3 is a flow chart illustrating a fabricating process of the wafer level substrate structure in FIG. 1A.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The figures are not drawn to scale and they are provided merely to illustrate the present invention. Several aspects of the invention are described below with reference to example applications for illustration. It should be understood that numerous specific details, relationships and methods are set forth to provide a full understanding of the invention. The present invention may be embodied in many different forms and should not be construed as limited to the embodiments set forth herein. For example, the present invention can be embodied as a method or a system.

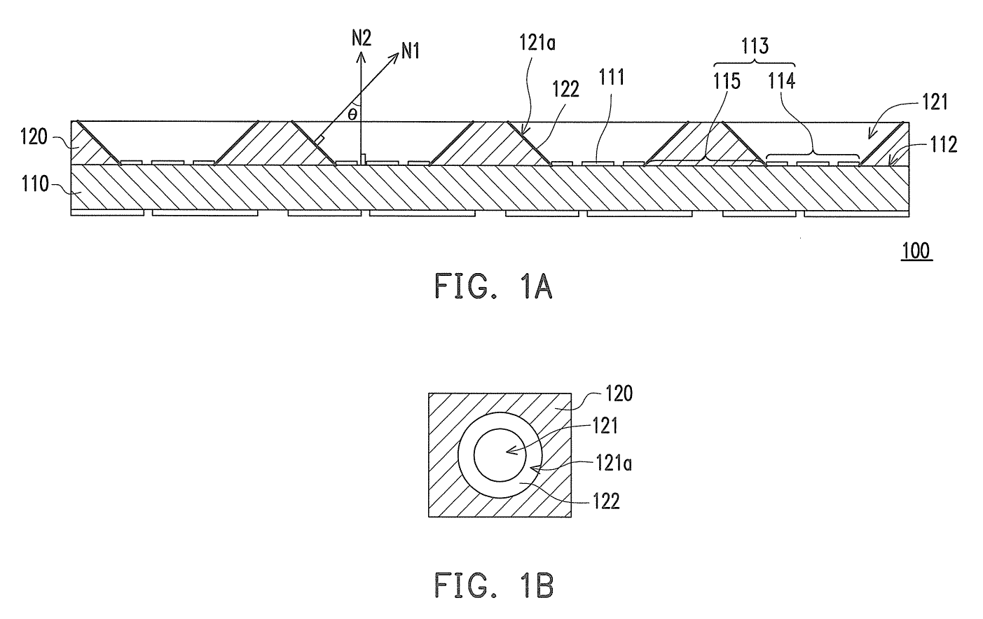

FIG. 1A is a cross-sectional view showing a wafer level substrate structure according to an embodiment of the present invention. Please refer to FIG. 1A. The wafer level silicon substrate structure 100 for carrying light emitting devices (LED) includes a first substrate 110 and a second substrate 120. The metal line 111 is constructed on a surface 112 of the first substrate 110 according to a predetermined pattern 113. The predetermined pattern 113 is divided into a plurality of first portions 114 and a plurality of second portions 115. The second substrate 120 is adhered to the surface 112 of the first substrate 110, and first substrate 110 and the second substrate 120 are connected by for example a wafer-to-wafer bonding method or a wafer-to-wafer stacked method. The second surface 120 has a plurality of through holes 121 formed on the second substrate 120, wherein the through holes 121 are respectively corresponding to the first portions 114. Each of the first portions 114 is adapted to electrically connect with at least one LED (not shown).

Moreover, in the embodiment, a reflective layer 122 is formed on an internal wall 121a of each of the through holes 121 such that the LED embedded inside the through holes 121 can provide uniform and high illumination light output. Herein, the reflectivity of the reflective layer 122 is more than 80 percent, and the reflective layer 122 of the embodiment is a metal layer, for example. The metal layer of the embodiment is made of for example gold (Au), silver (Ag), nickel (Ni), chromium (Cr), Aluminum (Al) or material composed thereof. And the reflective layer 122 may be formed by a coating, electroplating, evaporation or sputter process.

In the embodiment, the first substrate 110 can be a silicon substrate or a ceramic substrate, and the second substrate 120 may be a glass substrate, a silicon substrate or a sapphire substrate. Besides, the through holes 121 of the second substrate 120 are formed by a computer numerical control (CNC) process, laser drilling process, dry etching process or wet etching process or any other suitable process to obtain a good light reflective performance. It should be noted that, since the second substrate 120 of the embodiment may be a glass substrate, a silicon substrate or a sapphire substrate. The shape and structure of the through holes 121 are not restricted by the crystal lattice structures of silicon. In other words, the through hole 121 of the embodiment formed by CNC process, laser drilling process, dry etching process or wet etching process can be a conical hole a rectangular hole, a square hole, or a trapezoidal hole, and the present invention is not limited thereto. Furthermore, as shown in FIG. 1A, an angle θ between a normal vector N1 of the internal wall 121a and a normal vector N2 of the surface 112 of the first substrate 110 is from 30 to 60 degrees. In this embodiment, when the through hole 121 is, for example, a conical hole as shown in FIG. 1A, the top-view of the through hole 121 of the wafer level substrate 100 is a circle as shown in FIG. 1B. And the configuration of LED can be more flexible since different shapes of through holes 121 can be obtained to embed the LED with various configurations. In other words, various types of wafer level substrate structure 100 can be obtained by changing the material and profile of the second substrate 120 so as to obtain various light emitting modules. Besides, the wafer level substrate structure 100 and the LED (not shown) may be connected through a technique of ball grid array (BGA) package or surface mount technology (SMT), or through general electric wires, and the invention is not limited thereto.

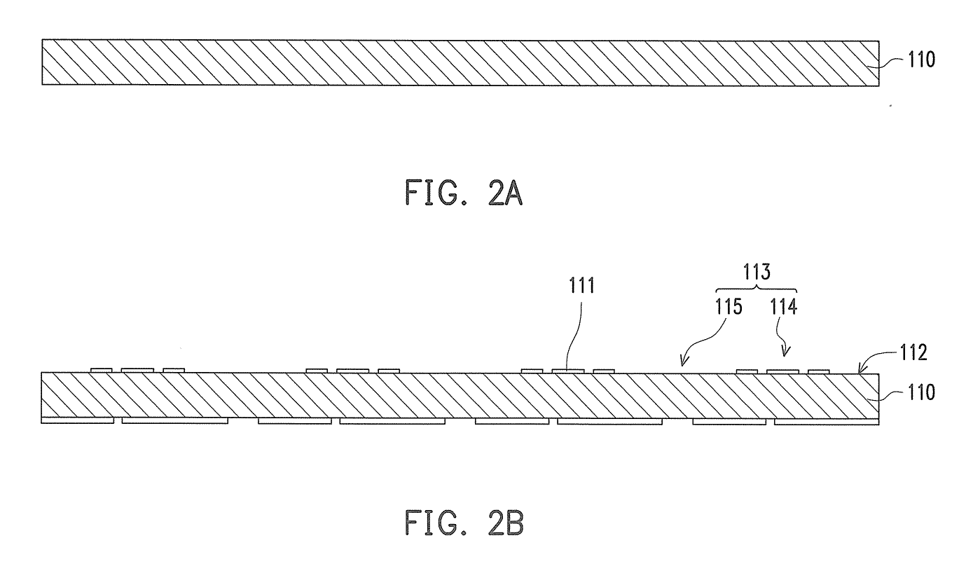

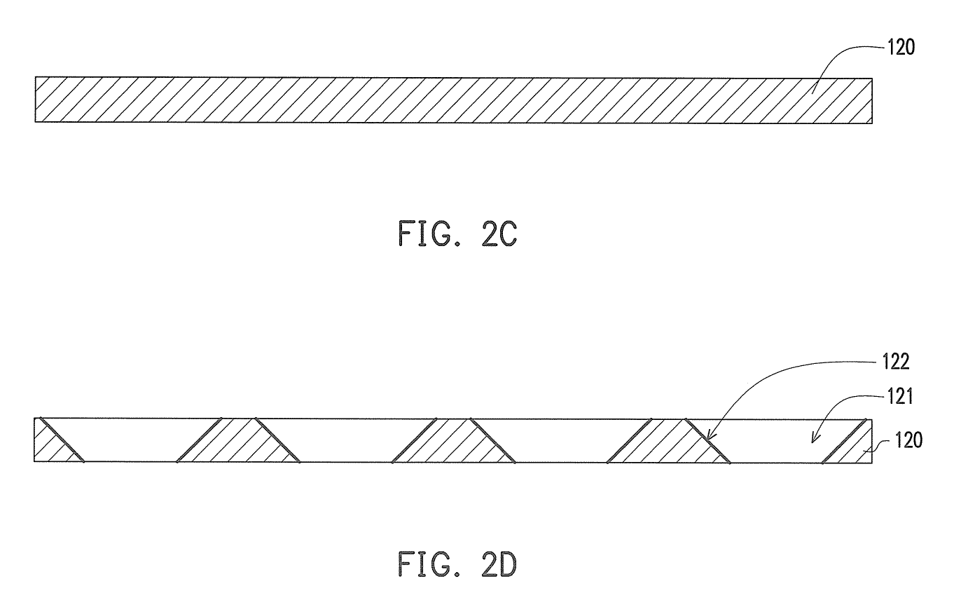

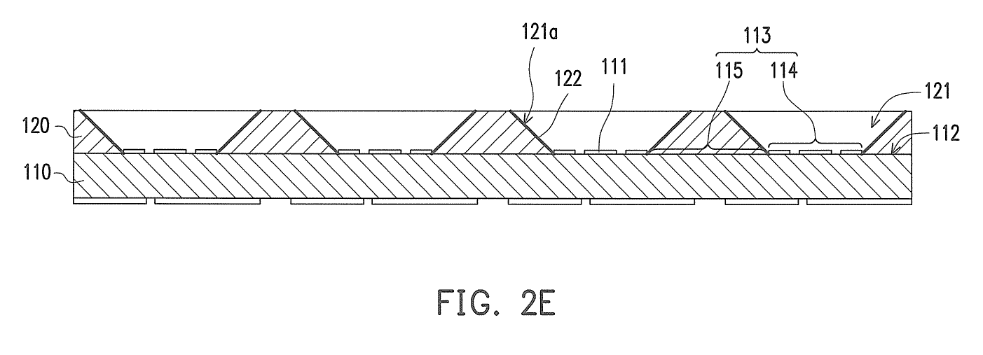

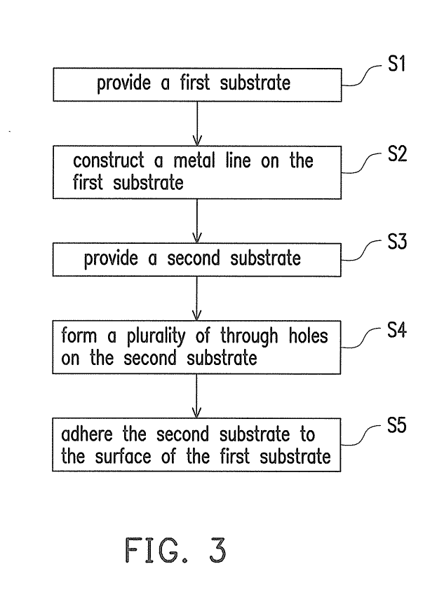

Furthermore, a method of fabricating the aforementioned wafer level substrate for carrying light emitting devices is also provided in the present invention. FIG. 2A to 2E is a cross-sectional view showing fabricating steps of the wafer level substrate structure in FIG. 1A. FIG. 3 is a flow chart illustrating a fabricating process of the wafer level substrate structure in FIG. 1A. Please refer to FIG. 2A to 2E and FIG. 3. A wafer level substrate structure 100 is conducted for carrying light emitting devices in the following steps. First, as shown in FIG. 2A, a first substrate 110 is provided (step S1). Then, as shown in FIG. 2B, on the first substrate 110, a metal line 111 is constructed (step S2). Herein the metal line 111 is constructed on a surface 112 of the first substrate 110 according to a predetermined pattern 113. The predetermined pattern 113 is divided into a plurality of first portions 114 and a plurality of second portions 115. Then, as shown in FIG. 2C, a second substrate 120 is provided (step S3). Then, as shown in FIG. 2D, a plurality of through holes 121 are formed on the second substrate 120 (step S4). Finally, as shown in FIG. 2E, the second substrate 120 is adhered to the surface 112 of the first substrate 110 S4 (step S5), wherein each of the through holes 121 is respectively corresponding to the first portions 114. Each of the first portions 114 is adapted to electrically connect with a light emitting device. And a reflective layer 122 is formed on the internal wall 121a of each of the through holes 121. In this way, the fabricating of the wafer level substrate structure for carrying light emitting devices is completed.

Based on the above, the wafer level substrate structure is provided with another substrate (i.e. the second substrate) having through holes to embed light emitting devices, wherein the second substrate is easy to process in forming the through holes with various shape and thus possible to avoid all the drawbacks obtained by etching silicon process. Through the using of the second substrate, the provided wafer level substrate structure for carrying light emitting devices is capable of providing uniform light output, having better light extraction property, improving process yield, higher production yield and achieving product uniformity. In addition, the shape and structure of the through hole is no longer restricted because of the easy-to-process second substrate is used in the present invention.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A wafer level substrate structure, for carrying light emitting devices, comprising:
a first substrate, wherein a metal line is constructed on a surface of the first substrate according to a predetermined pattern, and the predetermined pattern is divided into a plurality of first portions and a plurality of second portions; and
a second substrate, adhered to the surface of the first substrate, and having a plurality of through holes, wherein each of the through holes is respectively corresponding to the first portions, and each of the first portions is adapted to electrically connect with at least one light emitting device.

2. The wafer level substrate structure according to claim 1, wherein the first substrate is a silicon substrate or a ceramic substrate, and the second substrate is a glass substrate, a silicon substrate or a sapphire substrate.

3. The wafer level substrate structure according to claim 1, wherein the through holes of the second substrate are formed by a computer numerical control process, laser drilling process, dry etching process or wet etching process.

4. The wafer level substrate structure according to claim 1, wherein each of the through holes has an internal wall and an angle between a normal vector of the internal wall and a normal vector of the surface of the first substrate is from 30 to 60 degrees.

5. The wafer level substrate structure according to claim 4, wherein the through hole is a conical hole, a rectangular hole, a square hole, or a trapezoidal hole.

6. The wafer level substrate structure according to claim 1, wherein a reflective layer is formed on an internal wall of each of the through holes.

7. The wafer level substrate structure according to claim 6, wherein a reflectivity of the reflective layer is greater than 80 percent.

8. The wafer level substrate structure according to claim 7, wherein the reflective layer is a metal layer.

9. The wafer level substrate structure according to claim 6, wherein the reflective layer is formed by a coating, electroplating, evaporation or sputter process.

10. The wafer level substrate structure according to claim 1, wherein the first substrate and the second substrate are connected by a wafer-to-wafer bonding method or a wafer-to-wafer stacked method.

11. The wafer level substrate structure according to claim 1, wherein the wafer level substrate structure and the light emitting device are connected through a technique of ball grid array package or surface mount technology, or through general electric wires.
